(19) United States
(12) Patent Application Publication
(10) Pub. No.: US 2012/0241733 A1
(43) Pub. Date: Sep. 27, 2012

(54) DISPLAY DEVICE, MANUFACTURING METHOD OF THE SAME AND ELECTRONIC EQUIPMENT HAVING THE SAME

(75) Inventors: Mitsuo Morooka, Kanagawa (JP); Yasunobu Hiromasu, Kanagawa (JP)

(73) Assignee: Sony Corporation, Tokyo (JP)

(21) Appl. No.: 13/417,381

(22) Filed: Mar. 12, 2012

(30) Foreign Application Priority Data
Mar. 24, 2011 (JP) 2011-066282

(51) Int. Cl. H01L 51/52; H01L 51/56

(52) U.S. Cl. 257/43; 438/34; 257/40; 257/E51.018

(57) ABSTRACT

Disclosed herein is a display device including a semiconductor layer, a gate electrode, a source/drain electrode layer, and an organic electric field light-emitting element. The semiconductor layer is provided on a substrate and made of an oxide semiconductor. The gate electrode is provided above a selective first region of the semiconductor layer with a gate insulating film sandwiched therebetween. The source/drain electrode layer is adapted to serve as a source or drain and electrically connected to a second region of the semiconductor layer adjacent to the first region thereof. Also, the organic electric field light-emitting element is provided above a third region of the semiconductor layer different from the first and second region thereof, the organic electric field light-emitting element having a region for the third region that is driven as a pixel electrode.

### BACKGROUND

The present disclosure relates to a display device having thin film transistors made of an oxide semiconductor, a manufacturing method of the same and electronic equipment having the same.

Recent years have seen the commercialization of TFTs (Thin Film Transistors) for driving flat panel displays such as liquid crystal and organic EL (Electro Luminescence) display devices. These TFTs are commonly manufactured by using semiconductor materials such as amorphous silicon or polycrystalline silicon on a substrate. However, using amorphous silicon leads to low electron field effect mobility while making it easy to transition to large panel sizes. On the other hand, using polycrystalline silicon makes it difficult to transition to larger panel sizes while offering high electron field effect mobility.

In contrast, it is known that oxides made of zinc, indium, gallium and tin or their mixtures (oxide semiconductors) can be formed into films at low temperatures and offer excellent semiconductor characteristics. More specifically, oxide semiconductor TFTs have a ten-fold or greater electron mobility than amorphous silicon TFTs and yet offer excellent OFF characteristics.

Recently, therefore, a variety of research and development efforts have been made to apply such oxide semiconductors to active matrix display devices (e.g., Japanese Patent Laid-Open No. 2004-192876 and Japanese Patent Laid-Open No. 2009-271527). Japanese Patent Laid-Open No. 2004-192876 proposes a method to simplify the manufacturing method by patterning the source electrode of the so-called top gate TFT for use as an electrode of an organic EL display device. On the other hand, Japanese Patent Laid-Open No. 2009-271527 proposes a structure in which an oxide semiconductor is used as an electrode of an organic EL display device.

### SUMMARY

Incidentally, in order to manufacture a drive substrate, TFTs and capacitors are formed first on a substrate and then coated with a planarizing film, followed by the formation of pixels, each including an organic EL element, on the planarizing film in the manufacturing steps of an organic EL display device. At this time, it is necessary to pattern each layer by photolithography using a so-called photomask. Therefore, a different photomask is necessary for the patterning of each layer. Further, more photoresist and other materials are consumed. The formed layers undergo coating, exposure, development, post-bake and other steps, thus resulting in more film formation steps and higher cost. Therefore, there is a demand to provide a smaller number of steps to achieve lower product cost and improved yield.

If the source electrode of a TFT is used as an electrode of an organic EL display device in a top gate structure as with the method described in Japanese Patent Laid-Open No. 2004-192876, the number of steps can be reduced as compared to if the electrode of the organic EL display device is formed separately. Even in this case, however, at least five photomasks are necessary (five photolithography steps are necessary). Therefore, there is a demand to achieve further reduction in number of steps and lower cost.

The present disclosure has been made in light of the foregoing, and it is desirable to provide a display device that can be manufactured by a low-cost and simple process, a manufacturing method of the same and electronic equipment having the same.

A display device according to an embodiment of the present disclosure includes: a semiconductor layer provided on a substrate and made of an oxide semiconductor; a gate electrode provided above a selective first region of the semiconductor layer with a gate insulating film sandwiched therebetween; a source/drain electrode layer adapted to serve as a source or drain and electrically connected to a second region of the semiconductor layer adjacent to the first region thereof; and an organic electric field light-emitting element provided above a third region of the semiconductor layer different from the first and second region thereof, the organic electric field light-emitting element having a region for the third region that is driven as a pixel electrode.

A manufacturing method of a display device according to the embodiment of the present disclosure includes: forming a semiconductor layer made of an oxide semiconductor on a substrate; forming a gate electrode above a selective first region of the semiconductor layer with a gate insulating film sandwiched therebetween; forming a source/drain electrode layer adapted to serve as a source or drain in such a manner to electrically connect the source/drain electrode layer to a second region of the semiconductor layer adjacent to the first region thereof; and forming an organic electric field light-emitting element above a third region of the semiconductor layer different from the first and second region thereof, the organic electric field light-emitting element having a region for the third region that is driven as a pixel electrode.

In the display device and manufacturing method of a display device according to the embodiment of the present disclosure, the gate electrode is provided above the selective first region of the semiconductor layer made of an oxide semiconductor with the gate insulating film sandwiched therebetween. The source/drain electrode layer is electrically connected to the semiconductor layer in the second region of the semiconductor layer adjacent to the first region thereof. The organic electric field light-emitting element is formed above the third region of the semiconductor layer different from the first and second region thereof. The organic electric field light-emitting element has the region for the third region that is driven as a pixel electrode. That is, the number of patterning steps based on photolithography can be reduced in the manufacturing steps by using, as an electrode of the organic electric field light-emitting element, the semiconductor layer adapted to form a transistor channel. This contributes to less consumption of photomasks, photoresist and other necessary materials.

Electronic equipment according to still another embodiment of the present disclosure has the above display device including: a semiconductor layer provided on a substrate and made of an oxide semiconductor; a gate electrode provided above a selective first region of the semiconductor layer with a gate insulating film sandwiched therebetween; a source/drain electrode layer adapted to serve as a source or drain and electrically connected to a second region of the semiconductor layer adjacent to the first region thereof; and an organic electric field light-emitting element provided above a third region of the semiconductor layer different from the first and second region thereof, the organic electric field light-emitting element having a region for the third region that is driven as a pixel electrode.

In the display device and manufacturing method of a display device according to the embodiment of the present disclosure, the gate electrode is provided above the selective first region of the semiconductor layer made of an oxide semiconductor with a gate insulating film sandwiched therebetween. The source/drain electrode layer is electrically connected to the semiconductor layer in the second region of the semiconductor layer adjacent to the first region thereof. The organic electric field light-emitting element is provided above the third region of the semiconductor layer different from the first and second region thereof. The organic electric field light-emitting element has the region for the third region that is driven as a pixel electrode. This provides a reduced number of patterning steps based on photolithography, thus contributing to less consumption of photomasks, photoresist and other necessary materials and thereby allowing for manufacture of the display device by a low-cost and simple process.

### BRIEF DESCRIPTION OF THE DRAWINGS

FIG. 1 is a cross-sectional view illustrating the schematic configuration of a display device according to an embodiment of the present disclosure;

FIGS. 2A to 2N are cross-sectional views for describing the manufacturing method of the display device shown in FIG. 1;

FIG. 3 is a cross-sectional view illustrating the schematic configuration of a display device according to a comparative example;

FIGS. 4A to 4F are cross-sectional views for describing the manufacturing method of a display device according to the comparative example;

FIG. 5 is a diagram illustrating the overall configuration including peripheral circuitry of the display device according to the embodiment;

FIG. 6 is a diagram illustrating the circuit configuration of a pixel shown in FIG. 5;

FIG. 7 is a plan view illustrating the schematic configuration of a module including the display device shown in FIG. 5;

FIG. 8 is a perspective view illustrating the appearance of application example 1;

FIG. 9A is a perspective view illustrating the appearance of application example 2 as seen from the front, and FIG. 9B is a perspective view illustrating the appearance thereof as seen from the back;

FIG. 10 is a perspective view illustrating the appearance of application example 3;

FIG. 11 is a perspective view illustrating the appearance of application example 4; and

FIG. 12A is a front view of application example 5 in an open position, FIG. 12B is a side view thereof, FIG. 12C is a front view in a closed position, FIG. 12D is a left side view, FIG. 12E is a right side view, FIG. 12F is a top view, and FIG. 12G is a bottom view.

### DETAILED DESCRIPTION OF THE PREFERRED EMBODIMENT

A detailed description will be given below of the preferred embodiment of the present disclosure with reference to the accompanying drawings. It should be noted that the description will be given in the following order.

1. Embodiment (example of an organic EL display device using the semiconductor layer of a TFT having a top gate structure as a display pixel electrode
2. Application examples (example of a module and those of electronic equipment)<

### Embodiment

### [Configuration of the Display Device 1]

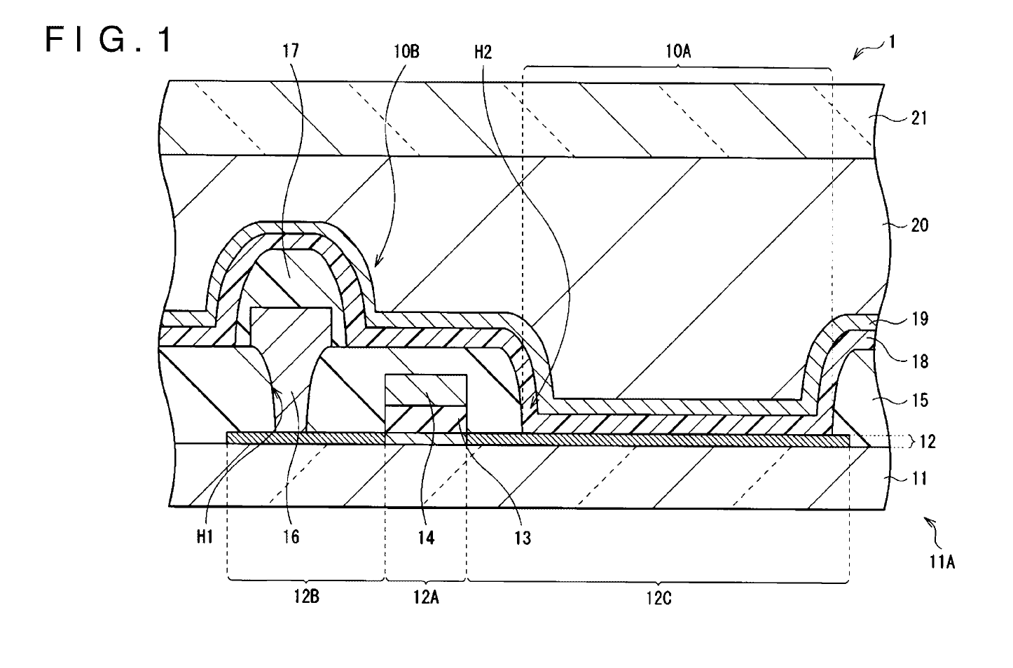

FIG. 1 illustrates the schematic configuration of a display device (display device 1) according to an embodiment of the present disclosure. The display device 1 is, for example, an active matrix organic EL display and has a plurality of pixels arranged in a matrix form. It should be noted, however, that FIG. 1 shows only the region for one pixel (e.g., one of red, green and blue subpixels). The display device 1 includes a functional layer 18, common electrode 19 and protective layer 20 on a drive substrate 11A. The functional layer 18 includes an organic EL layer. A sealing substrate 21 is attached to the protective layer 20 using an unshown adhesive layer. The display device 1 may be a so-called top emission or bottom emission display device.

In the drive substrate 11A, a transistor section 10B is provided on a substrate 11 to drive the pixel. Although described in detail later, the transistor section 10B is a top gate thin film transistor (TFT) having its channel (active layer) made of an oxide semiconductor. In the present embodiment, although described in detail later, the drive substrate 11A has a laminated structure in which part of a semiconductor layer 12 of the transistor section 10B serves as (is used as) a pixel electrode (e.g., anode).

The functional layer 18 includes an organic EL layer (light-emitting layer) adapted to emit light when applied with a drive current. The same layer 18 is made up, for example, of a hole injection layer, hole transport layer, organic EL layer and electron transport layer (none of them are shown) that are stacked in this order from the side of the substrate 11. The organic EL layer emits light as a result of the recombination of electrons and holes when applied with an electric field. It is only necessary for the organic EL layer to be made of an ordinary low or high molecular weight organic material. The material of the organic EL layer is not specifically limited. On the other hand, the red, green and blue light-emitting layers may be, for example, patterned side by side, one for each pixel. Alternatively, a white light-emitting layer (layer made up, for example, of red, green and blue light emitting layers stacked one on top of another) may be provided so that the same layer can be shared among all the pixels. The hole injection layer is designed to provide enhanced hole injection efficiency and prevent leaks. The hole transport layer is designed to provide enhanced hole transport efficiency to the organic EL layer. It is only necessary to provide these layers other than the organic EL layer as necessary. It should be noted that an electron injection layer (not shown) may further be provided between the functional layer 18 and common electrode 19 as necessary.

The functional layer 18 configured as described above is provided, for example, above the entire surface of the substrate 11. However, the region that actually emits light is that (light-emitting section 10A) for an opening H2 (second opening) in an interlayer insulating film 15 which will be described later.

The common electrode 19 acts, for example, as a cathode and includes a metal conductive film. For example, if the display device 1 is a bottom emission display device, the common electrode 19 includes a reflective metal film, more specifically, a single-layer film made of an elemental metal including at least one of aluminum (Al), magnesium (Mg), calcium (Ca), silver (Ag) and sodium (Na) or an alloy containing at least one of the above, or a multilayer film made up of two or more layers of the above metals stacked one on top of another. Alternatively, if the display device 1 is a top emission display device, the common electrode 19 includes a transparent conductive film made, for example, of ITO. The common electrode 19 is formed on the functional layer 18 while being insulated from the anode (pixel electrode section 12C of the semiconductor layer 12 in the present embodiment which will be described later) so that the same electrode 19 can be shared among all the pixels. It should be noted that the common electrode 19 may act as an anode.

The protective layer 20 may be made of an insulating or conductive material. Among insulating materials that can be used are amorphous silicon (a-Si), amorphous silicon carbide (a-SiC), amorphous silicon nitride (a-Si_{1-X}N_{X}) and amorphous carbon (a-C).

The sealing substrate 21 includes a plate material made, for example, of quartz, glass, metal foil, silicon or plastic. It should be noted, however, that if the display device 1 is a top emission display device, the sealing substrate 21 includes a transparent substrate made, for example, of glass or plastic and may have, for example, an unshown color filter or light-shielding film.

### [Detailed Configuration of the Drive Substrate 11a]

The drive substrate 11A includes the transistor section 10B provided above the substrate 11 as described above. Part of the transistor section 10B acts as an electrode adapted to drive the pixel.

The substrate 11 includes a plate material made, for example, of quartz, glass, metal foil, silicon or plastic. It should be noted, however, that if the display device 1 is a bottom emission display device, the substrate 11 includes a transparent substrate made, for example, of glass or plastic.

The transistor section 10B corresponds to a sampling transistor 5A or drive transistor 5B in a pixel drive circuit 50a which will be described later and is a TFT having an inverted staggered (so-called top gate) structure. The same section 10B has a semiconductor layer 12 arranged in a predetermined region on the substrate 11, and a gate insulating film 13 and gate electrode 14 are arranged in this order in a selective region (channel region 12A (first region)) on the semiconductor layer 12. The semiconductor layer 12, gate insulating film 13 and gate electrode 14 are covered with the interlayer insulating film 15 on and above the substrate 11.

The semiconductor layer 12 forms a channel when applied with a gate voltage and includes, for example, an oxide semiconductor containing at least one of indium (In), gallium (Ga), zinc (Zn), silicon (Si) and tin (Sn). Indium gallium zinc oxide (IGZO or InGaZnO) is among such oxide semiconductors. This oxide semiconductor film 12 is, for example, 20 to 100 nm in thickness.

The gate insulating film 13 is a single-layer film made up, for example, of one of silicon oxide film (SiOₓ), silicon nitride film (SiN) and silicon oxynitride film (SiON) or a laminated film made up of two or more layers of the above materials.

The gate electrode 14 serves as an interconnect adapted to control the carrier density of the semiconductor layer 12 based on a gate voltage (Vg) applied to the transistor section 10B and supply a potential. The same electrode 14 includes a film made, for example, of one of molybdenum (Mo), titanium (Ti), aluminum (Al), silver (Ag) and copper (Cu) or an alloy thereof, or a laminated film made of two or more of the above metals. More specifically, the gate electrode 14 has, for example, a laminated structure containing a metal layer made of a low-resistance material such as aluminum or silver sandwiched between molybdenum or titanium films. Alternatively, the same electrode 14 is made, for example, of an aluminum-neodymium alloy (AlNd alloy). Still alternatively, the gate electrode 14 may include a transparent conductive film made, for example, of ITO (indium tin oxide), AZO (aluminum-doped zinc oxide) or GZO (gallium-doped zinc oxide).

The interlayer insulating film 15 includes, for example, an organic insulting film made of polyimide, novolac resin or acrylic-based resin or an inorganic insulating film made of silicon oxide, silicon nitride or silicon oxynitride. It should be noted, however, that the interlayer insulating film 15 should preferably be made of a photosensitive resin used, for example, as photoresist. Using a photosensitive resin makes it possible to form a gentle taper in the interlayer insulating film 15 (more specifically, the opening portion thereof), thus preventing poor formation (e.g., so-called breakage) of the functional layer 18 formed thereon. Further, using a photosensitive resin eliminates the need for an etching step during patterning. This also makes the use of a photosensitive resin more advantageous than using other types of insulating films also in that the film formation process can be simplified.

In the present embodiment, a contact hole H1 (first opening) and the opening H2 (second opening) are provided in the interlayer insulating film 15 to be opposed to the semiconductor layer 12. The contact hole H1 is used to ensure electrical connection between a source/drain electrode layer 16 which will be described later and the semiconductor layer 12. The same hole H1 is provided to be opposed to the region (source/drain connection region 12B (second region)) adjacent to the channel region 12A of the semiconductor layer 12. The source/drain electrode layer 16 is formed on the interlayer insulating film 15 in such a manner as to fill the contact hole H1.

The opening H2 provided in the interlayer insulating film 15 partitions the light-emitting section 10A in each pixel (isolates each pixel). The same hole H2 is provided to be opposed to a region (pixel electrode section 12C (third region)) different from the channel region 12A and source/drain connection region 12B of the semiconductor layer 12. If a photosensitive resin is used as the interlayer insulating film 15 as described above, the surface (side surface) of the opening H2 is gently tapered (rounded).

In the light-emitting section 10A, the pixel electrode section 12C of the semiconductor layer 12 is provided in contact with the functional layer 18 in the opening H2 so that the same section 12C serves as a pixel electrode (anode in this case) in each pixel. That is, part of the semiconductor layer 12, the source electrode (or drain electrode) and the display pixel electrode (anode) are integral with each other. In other words, part of the semiconductor layer 12 serves also as a source electrode (or drain electrode) and pixel electrode (anode). The pixel electrode section 12C is formed, for example, to have a predetermined area size in a region other than the channel region 12A and source/drain connection region 12B. Here, the oxide semiconductor as described above is used as the semiconductor layer 12. However, this oxide semiconductor is transparent to visible light and has a large work function at the same time, making it possible for the oxide semiconductor to serve as a display electrode.

As described above, the semiconductor layer 12 has three regions (channel region 12A, source/drain connection region 12B and pixel electrode section 12C) different in functionality from each other. Of the three regions, the source/drain connection region 12B and pixel electrode section 12C are lower in electrical resistivity than the channel region 12A. As a result, in the semiconductor layer 12, the channel region 12A has semiconductor characteristics. In contrast, each of the source/drain connection region 12B and pixel electrode section 12C serves as an electrode or interconnect. It should be noted that such a reduction in resistance of the source/drain connection region 12B and pixel electrode section 12C can be achieved by subjecting the oxide semiconductor making up the semiconductor layer 12, for example, to plasma treatment.

The source/drain electrode layer 16 serves as a drain or source of the transistor section 10B and includes a metal or transparent conductive film similar to those listed for the gate electrode 14. A protective film 17 is formed on the interlayer insulating film 15 in such a manner as to cover the source/drain electrode layer 16.

The protective film 17 includes, for example, an organic insulting film made of polyimide, novolac resin or acrylic-based resin or an inorganic insulating film made of silicon oxide, silicon nitride or silicon oxynitride. It should be noted, however, that the same film 17 should preferably be made, for example, of a photosensitive resin used as photoresist. If a photosensitive resin is used, and if reflow is performed with the photoresist used for the patterning of the source/drain electrode layer 16 left unremoved on the same layer 16, it is possible to form the protective film 17 in such a manner as to cover the side surface (edge portion) of the source/drain electrode layer 16. This prevents electrical contact between the source/drain electrode layer 16 and functional layer 18, thus providing enhanced insulation therebetween.

### [Manufacturing Method]

The display device 1 as described above can be manufactured, for example, as described below. First, the pattern of the drive substrate 11A is formed using photolithography technique. For example, each film is formed first, followed by steps including coating with photoresist, pre-bake, exposure using a photomask, development, post-bake, etching (wet or dry) and photoresist removal, after which the film is patterned. More specifically, the drive substrate 11A is manufactured by the following procedure.

That is, the pattern of the semiconductor layer 12 is formed in a predetermined region of the substrate 11. More specifically, the semiconductor layer 12 made of the above oxide semiconductor is formed, for example, by sputtering over the entire surface of the substrate 11. At this time, if IGZO, for example, is used as an oxide semiconductor, reactive sputtering is performed using an IGZO ceramic target. At this time, the chamber of the DC sputtering system is exhausted to a predetermined vacuum level first. Then, the target and substrate 11 are placed to be opposed to each other in the chamber, after which a mixture gas of argon (Ar) and oxygen (O₂), for example, is introduced into the chamber for plasma discharge.

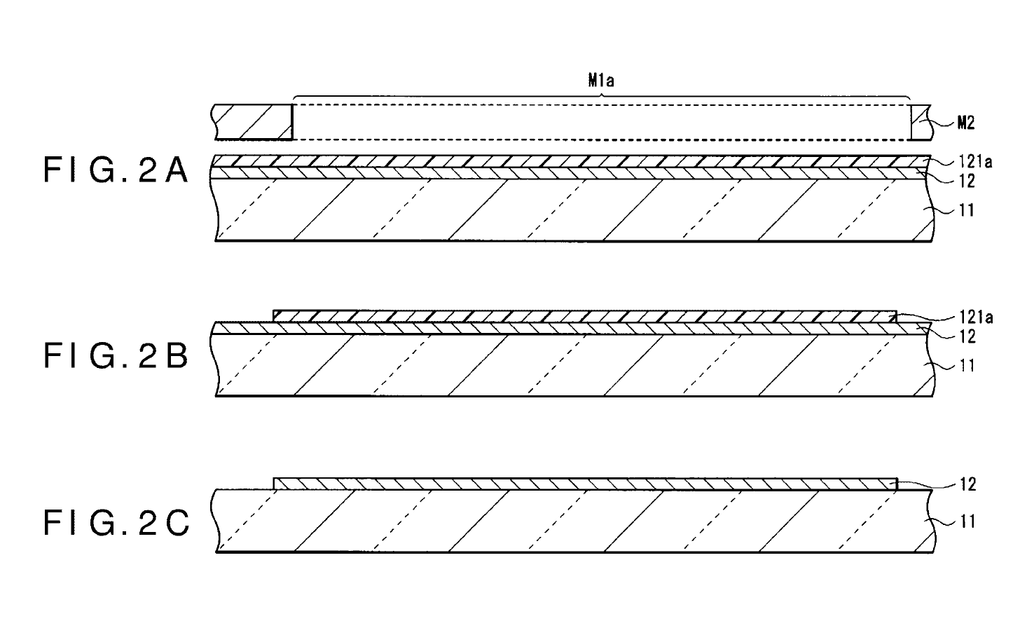

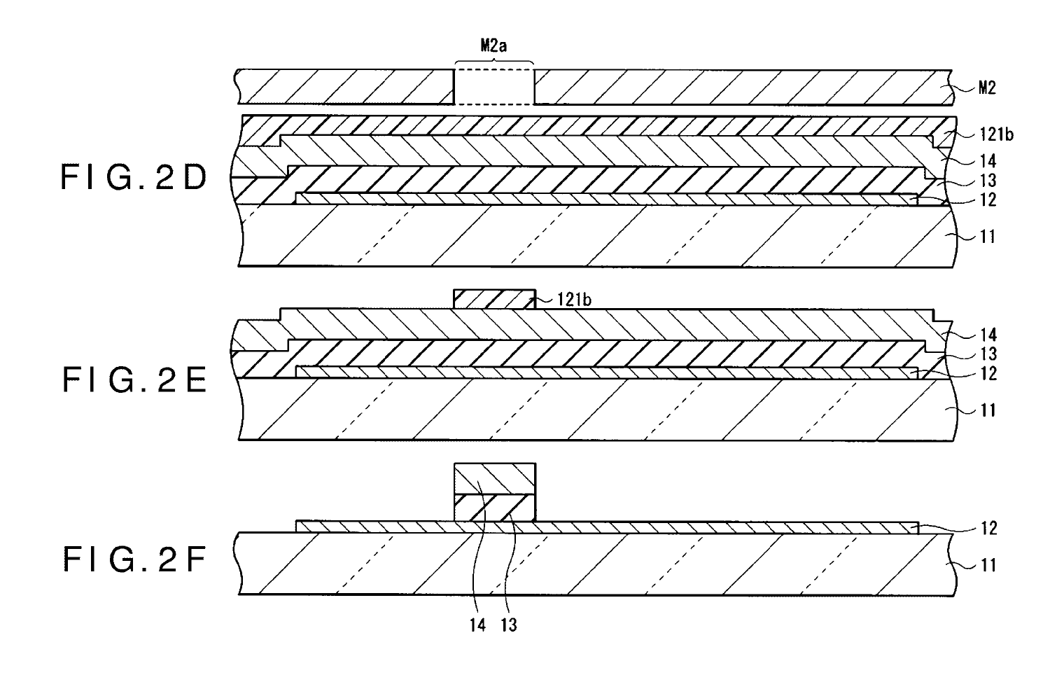

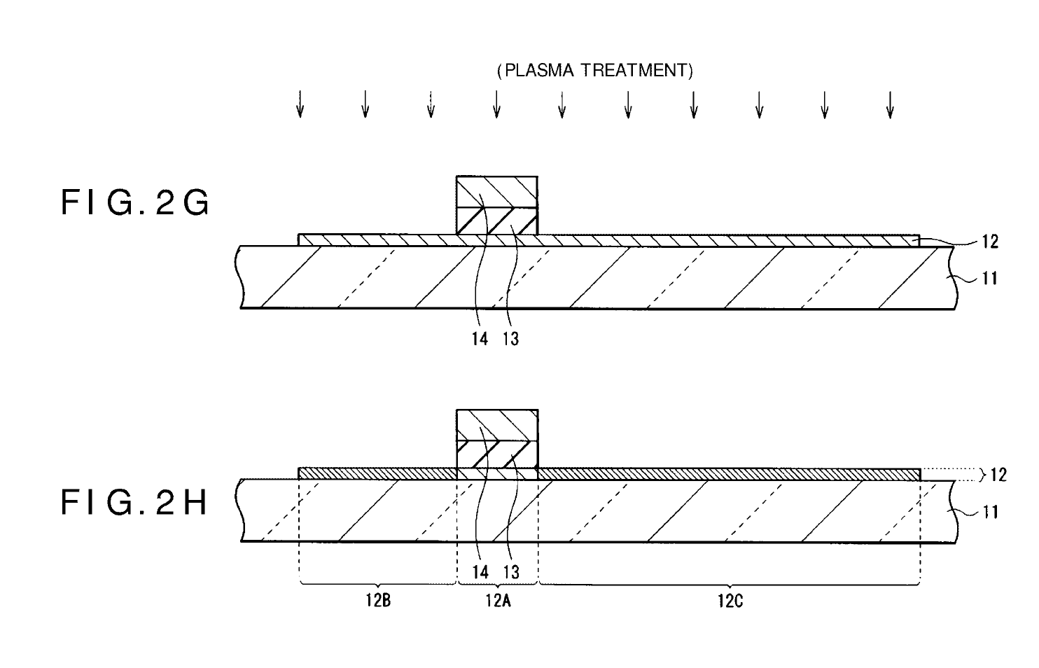

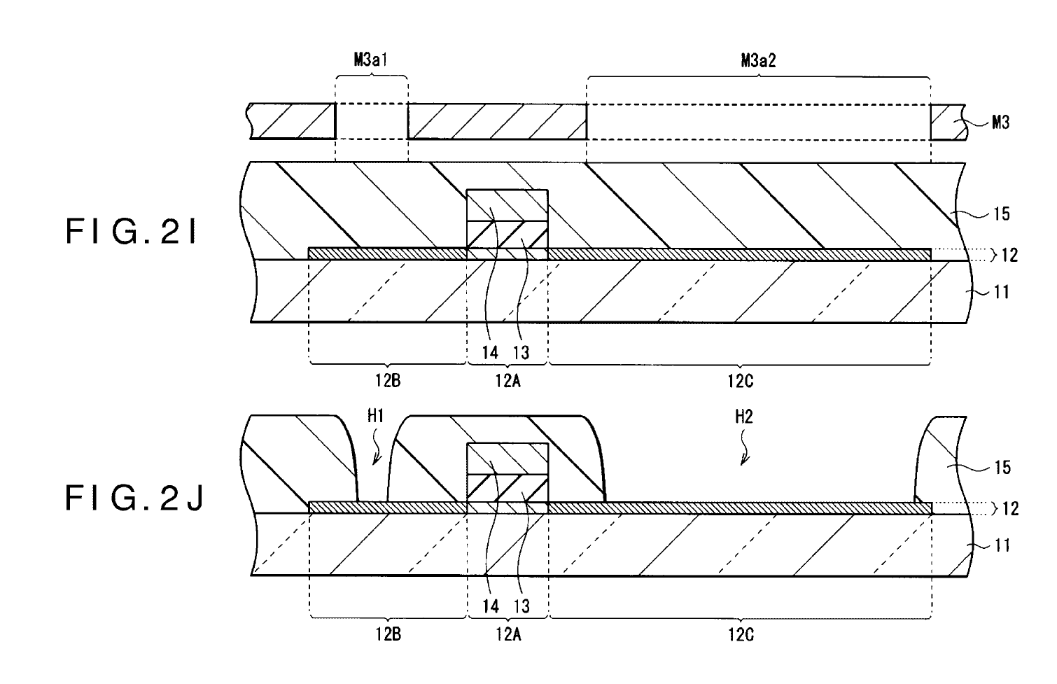

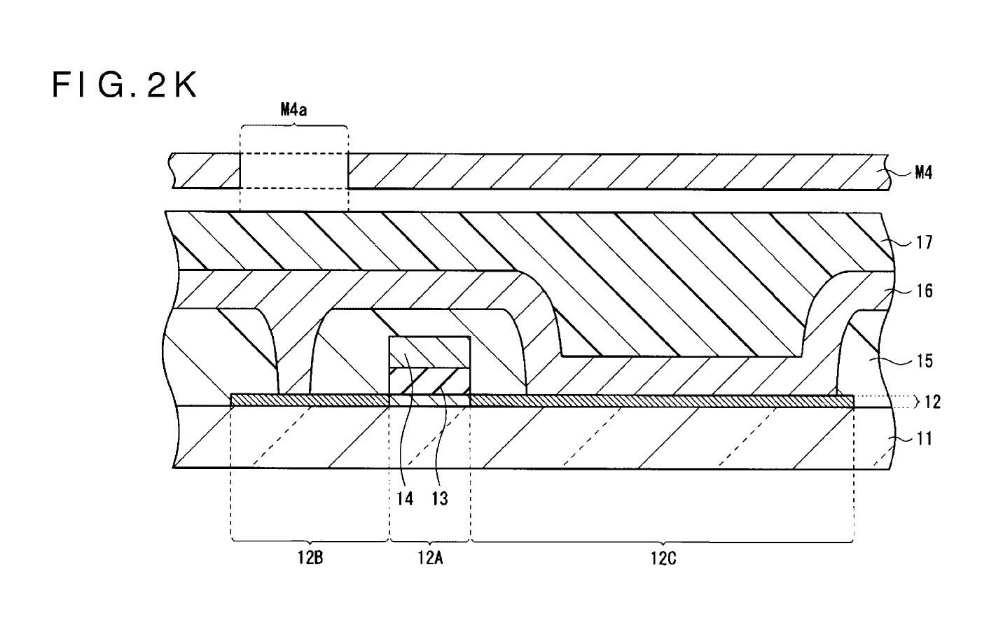

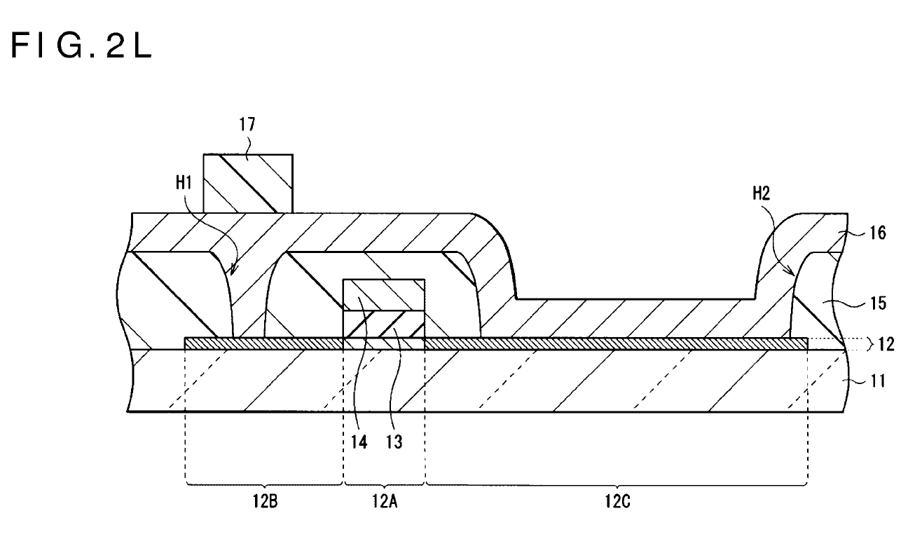

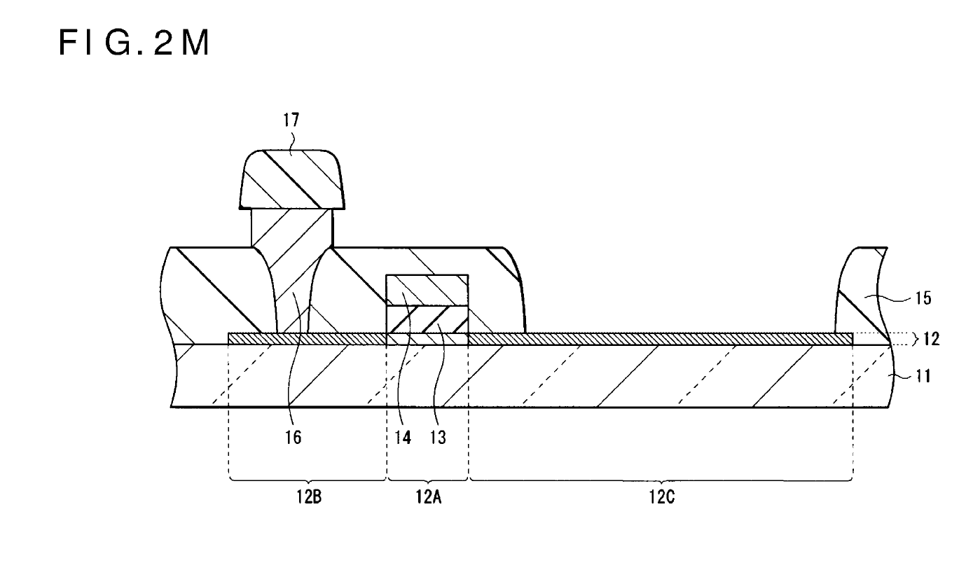

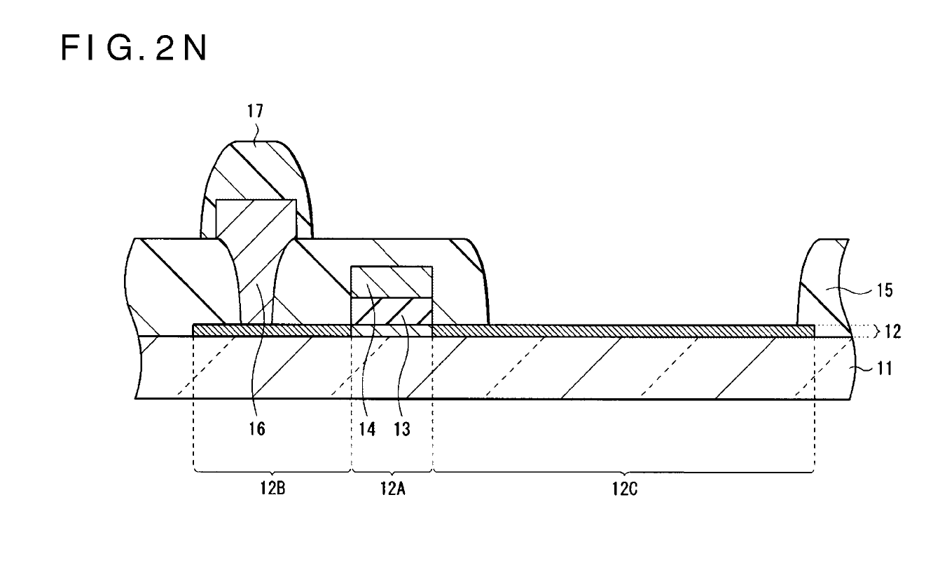

Then, the semiconductor layer 12 is patterned by photolithography. More specifically, as illustrated in FIG. 2A, the semiconductor layer 12 is coated with a photoresist 121a, after which the photoresist 121a is exposed in a pattern using a photomask M1 having an opening M1a. It should be noted that although a case is described here in which a positive photoresist is used as the photoresist 121a, a negative photoresist may be used as the photoresist 121a (the same applies hereinafter).

As a result, the photoresist 121a remains unremoved in the predetermined region (region for the opening M1a) on the semiconductor layer 12 as illustrated in FIG. 2B. Then, wet etching is, for example, performed, thus removing the exposed portion of the photoresist 121a from the semiconductor layer 12. After the etching, the photoresist 121a is peeled off (removed), thus forming the pattern of the semiconductor layer 12 as shown in FIG. 2C. It should be noted that, after the above, the semiconductor layer 12 is subjected to N₂O plasma treatment prior to the formation of the gate insulating film 13, thus introducing oxygen into the oxide semiconductor.

Next, the gate insulating film 13 and gate electrode 14 are formed in a selective region on the semiconductor layer 12. That is, the gate insulating film 13 made of the above material is formed, for example, by a CVD (Chemical Vapor Deposition) above the entire surface of the substrate 11, followed by the formation of the gate electrode 14 made of the above material, for example, by sputtering. At this time, if a silicon nitride film is formed as the gate insulating film 13, a mixture gas containing silane (SiH₄), ammonium (NH₃) and nitrogen is used as a raw material gas. Alternatively, if a silicon oxide film is formed, a mixture gas containing silane and dinitrogen oxide (N₂O) is used.

Then, the gate insulating film 13 and gate electrode 14 are patterned all together by photolithography. More specifically, as illustrated in FIG. 2D, the laminated film made up of the gate insulating film 13 and gate electrode 14 is coated with a photoresist 121b, after which the photoresist 121b is exposed in a pattern using a photomask M2 having an opening M2a. As a result, the photoresist 121b remains unremoved in the predetermined region (region for the opening M2a) on the gate electrode 14 as illustrated in FIG. 2E. Then, dry etching is, for example, performed, thus removing the portions of the gate insulating film 13 and gate electrode 14 that are not opposed to the photoresist 121b. After the etching, the photoresist 121b is removed, thus forming the patterns of the gate insulating film 13 and gate electrode 14 as illustrated in FIG. 2F.

Next, as illustrated in FIG. 2G, the semiconductor layer 12 is subjected, for example, to argon plasma treatment. At this time, the plasma treatment is performed using the gate insulating film 13 and gate electrode 14 formed in the previous step as masks. As a result, of the regions of the semiconductor layer 12, the electrical resistance of those not opposed to the gate insulating film 13 and gate electrode 14 (those exposed from the gate insulating film 13 and gate electrode 14) can be reduced. This divides the semiconductor layer 12 into three regions (channel region 12A, source/drain connection region 12B and pixel electrode section 12C) in terms of functionality as shown in FIG. 2H.

Then, the pattern of the interlayer insulating film 15 is formed on and above the substrate 11. That is, as illustrated in FIG. 2I, the semiconductor layer 12 is coated with the interlayer insulating film 15 on and above the entire surface of the substrate 11, for example, by spin coating or slit coating. It should be noted that a case will be described here in which a photosensitive resin is used as the interlayer insulating film 15 as mentioned earlier. Next, the interlayer insulating film 15 formed as described above is patterned by photolithography. That is, the same film 15 is exposed in a pattern using a photomask M3 having predetermined openings M3a1 and Mia. As a result, the contact hole H1 is formed to be opposed to the source/drain connection region 12B of the semiconductor layer 12, and the opening H2 to the pixel electrode section 12C as illustrated in FIG. 2J, thus exposing part of the surface of the semiconductor layer 12. Using a photosensitive resin as the interlayer insulating film 15 eliminates the need for an etching step. Further, a gentle taper is formed on the surface of the same film 15 near the opening H2 after the pattern exposure. As a result, it is possible to prevent breakage and other breakages of the functional layer 18 which will be formed in a later step.

Next, the pattern of the source/drain electrode layer 16 is formed. That is, the same layer 16 is formed, for example, by depositing the above conductive material over the entire surface of the interlayer insulating film 15 by sputtering. Then, the source/drain electrode layer 16 is patterned by photolithography. More specifically, as illustrated in FIG. 2K, the source/drain electrode layer 16 is coated with the protective film 17 made of the above photosensitive resin over the entire surface of the same layer 16 (the photoresist used for the patterning of the source/drain electrode layer 16 is used as the protective film 17). Then, the formed protective film 17 is exposed in a pattern using a photomask M4 having an opening M4a. As a result, the protective film 17 is patterned, leaving the same film 17 unremoved in the predetermined region (region for the contact hole H1) on the source/drain electrode layer 16 as illustrated in FIG. 2L.

Next, as illustrated in FIG. 2M, wet etching is, for example, performed, selectively removing the portion of the source/drain electrode layer 16 exposed from the protective layer 17. As described above, the pattern of the source/drain electrode layer 16 electrically connected to the semiconductor layer 12 (more specifically, the source/drain connection region 12B) is formed in such a manner as to fill the contact hole H1 on the interlayer insulating film 15. It should be noted that the protective film 17 hangs out over the edge of the side surface of the source/drain electrode layer 16 (so-called overhung shape) as a result of this etching.

Then, the protective film 17 remaining unremoved from the source/drain electrode layer 16 is heated for reflow without being peeled off, and is thereafter cured. This forms the protective film 17 that covers the entire surface of the source/drain electrode layer 16 including the side surface thereof as shown in FIG. 2N. This protective film 17 prevents electrical contact between the functional layer 18 which will be formed in a later step and the source/drain electrode layer 16, thus providing improved insulation therebetween.

It should be noted that the protective layer 17 need not fully cover the side surface of the source/drain electrode layer 16. That is, the protective film 17 may be left in an overhung shape without being reflowed after the etching of the source/drain electrode layer 16. Even if the protective film 17 is in such a condition, the same film 17 serves as a mask during the formation of the functional layer 18, making it unlikely for the organic material to adhere to the side surface of the source/drain electrode layer 16 and possibly ensuring insulation between the source/drain electrode layer 16 and functional layer 18. Here, the protective film 17 should preferably be reflowed to cover the entire surface of the source/drain electrode layer 16 for enhanced insulation.

Then, the functional layer 18 is formed above the drive substrate 11A, for example, by vacuum vapor deposition, followed by the formation of the common electrode 19 made of the above material, for example, by sputtering. Next, the protective layer 20 is formed, after which the sealing substrate 21 is attached to the protective layer 20, thus completing the manufacture of the display device 1 shown in FIG. 1.

### [Action and Effect]

When a drive current commensurate with the video signal of each of red, green and blue is applied to each of the red, green and blue pixels in the display device 1, electrons and holes are injected into the functional layer 18 via the pixel electrode section 12C (anode) and the common electrode 19 (cathode). The electrons and holes recombine in the organic EL layer included in the functional layer 18, thus emitting light. The display device 1 displays full color RGB images as described above.

In the display device 1 (drive substrate 11A) according to the present embodiment, the gate insulating film 13 and gate electrode 14 are provided in a selective region (channel region 12A) on the semiconductor layer 12. In the region (source/drain connection region 12B) adjacent to the channel region 12A, the source/drain electrode layer 16 is electrically connected to the semiconductor layer 12. In the semiconductor layer 12, a region (pixel electrode section 12C) different from the channel region 12A or source/drain connection region 12B is used as an anode.

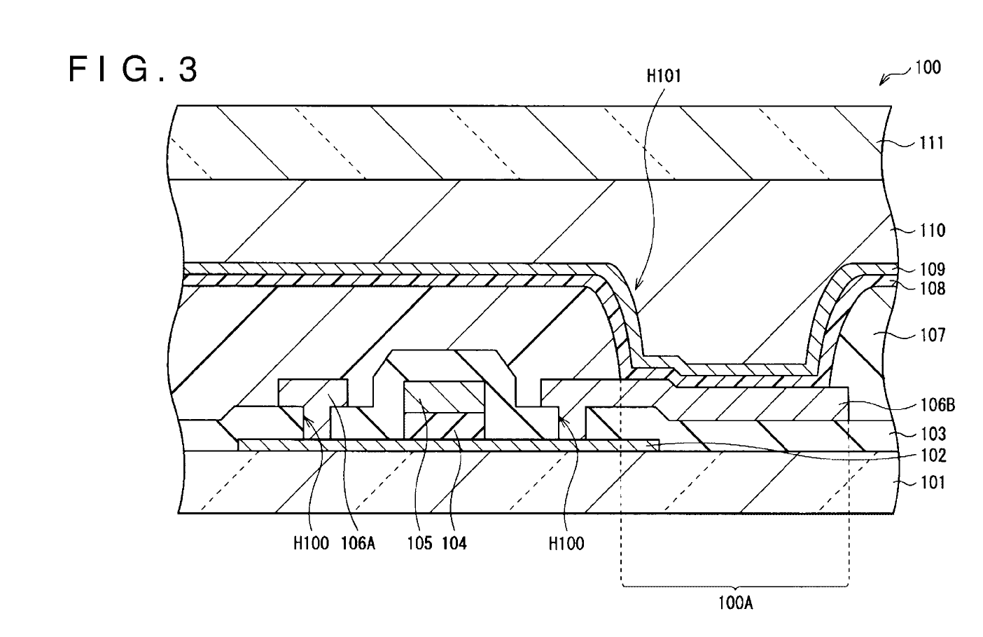

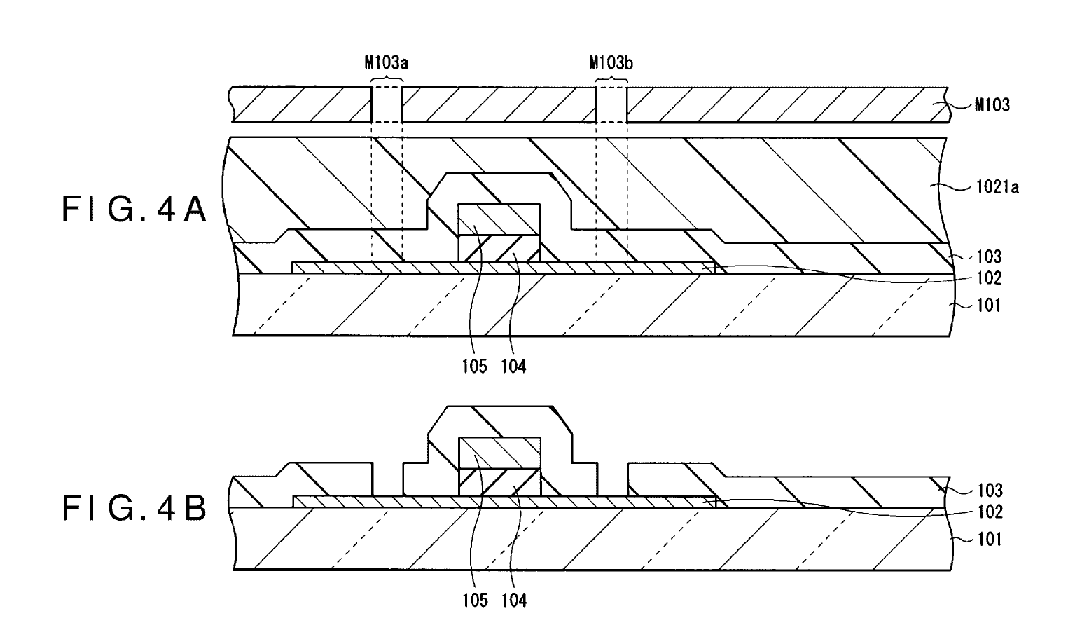

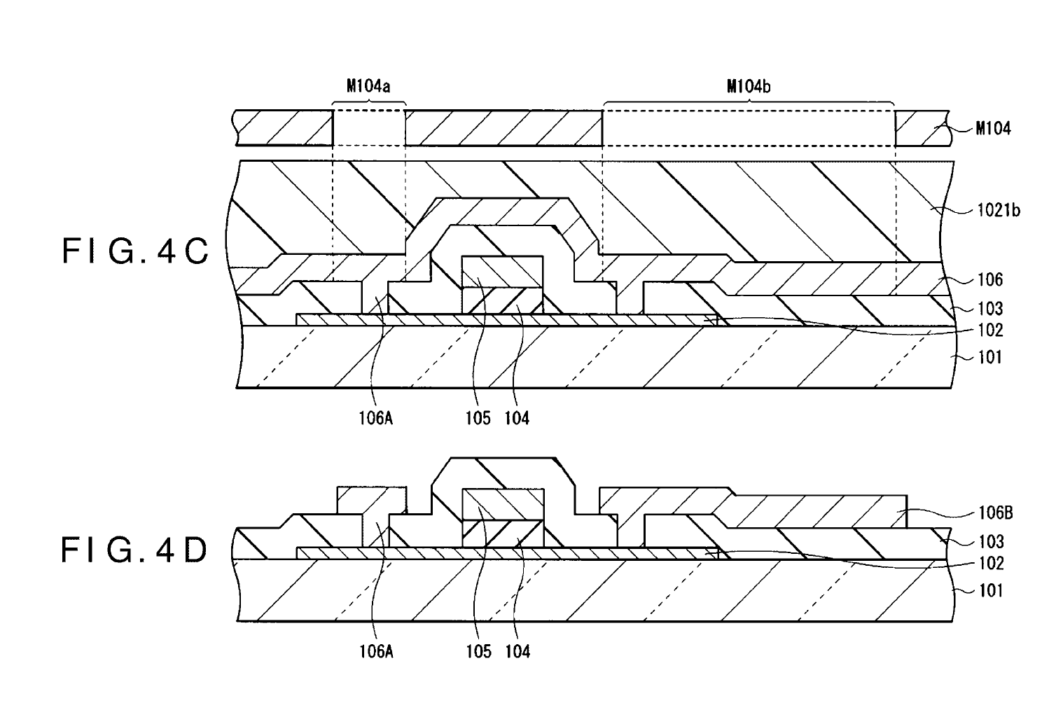

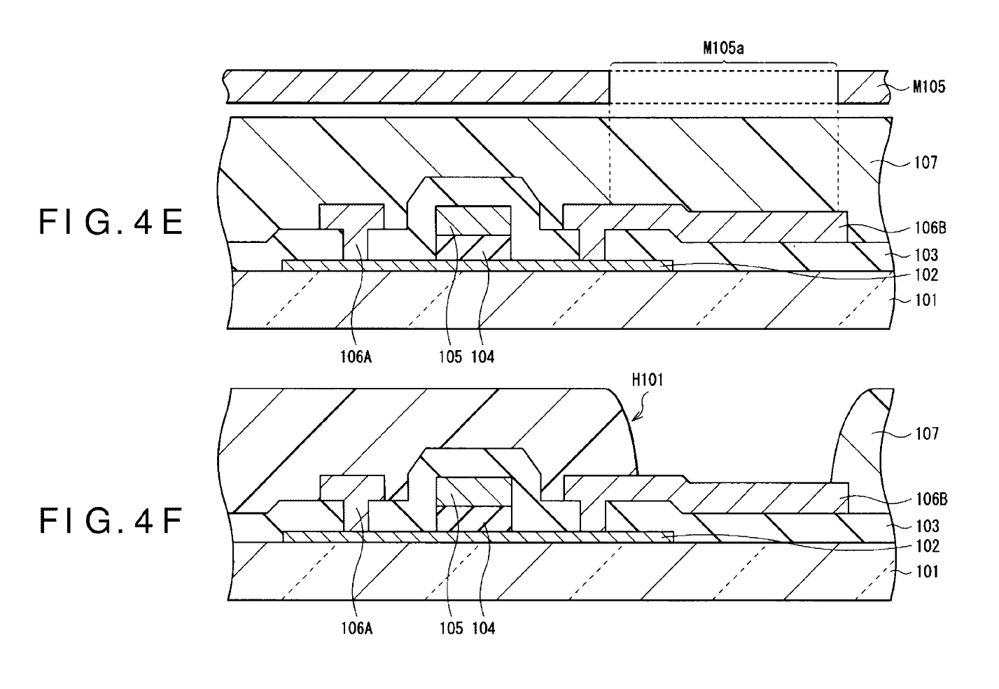

Here, FIG. 3 illustrates the cross-sectional structure of a display device (display device 100) using a source electrode (or drain electrode) as a display pixel electrode as a comparative example of the present embodiment. Further, FIGS. 4A to 4F illustrate some steps of the manufacturing method of the drive substrate used in the display device 100.

In the display device 100, a semiconductor layer 102 is provided in a predetermined region on a substrate 101, and a gate insulating film 104 and gate electrode 105 are arranged in this order in a selective region on the semiconductor layer 102. An interlayer insulating film 103 is formed on and above the substrate 101 in such a manner as to cover the semiconductor layer 102, gate insulating film 104 and gate electrode 105. The interlayer insulating film 103 includes an inorganic insulating film made, for example, of silicon oxide and has contact holes H100 in the region opposed to the semiconductor layer 102. A source electrode 106A and drain electrode 106B are provided on the interlayer insulating film 103 in such a manner as to fill the contact holes H100. One of the source electrode 106A and drain electrode 106B (drain electrode 106B in this case) extends to the region for a light-emitting section 100A. That is, in the comparative example, the drain electrode 106B serves also as an anode of the pixel. In the region for the light-emitting section 100A of the drain electrode 106B, a functional layer 108 including an organic EL layer and a common electrode 109 are stacked in this order in an opening H101 of an insulating film 107. A protective layer 110 is provided on the common electrode 109, and a sealing substrate 111 is attached to the protective layer 110.

The drive substrate of the display device 100 configured as described above is manufactured, for example, as described below. That is, the semiconductor layer 102 is formed on the substrate 101 by photolithography using a photomask M101 (not shown) first, followed by the pattern formation of the gate insulating film 104 and gate electrode 105 all together on the semiconductor layer 102 using a photomask M102 (not shown).

Next, as illustrated in FIG. 4A, the interlayer insulating film 103 is formed, for example, by the CVD above the entire surface of the substrate 101, followed by the coating with a photoresist 1021a. The photoresist 1021a is exposed in a pattern using a photomask M103 having an opening M103a in a predetermined region. Then, the interlayer insulating film 103 is etched, followed by the peeling-off of the photoresist 1021a, thus forming the contact holes H100 as illustrated in FIG. 4B.

Next, as illustrated in FIG. 4C, an electrode layer 106 which will serve as the source electrode 106A and drain electrode 106B is formed, for example, by sputtering over the entire surface of the interlayer insulating film 103, followed by the coating with a photoresist 1021b. The photoresist 1021b is exposed in a pattern using a photomask M104 having an opening M104a in a predetermined region. Then, the electrode layer 106 is etched, followed by the peeling-off of the photoresist 1021b, thus forming the source electrode 106A and drain electrode 106B as illustrated in FIG. 4D.

Next, as illustrated in FIG. 4E, the insulating film 107 made, for example, of a photosensitive resin, is formed above the entire surface of the substrate 101, followed by the pattern exposure of the same film 107 using a photomask M105 having an opening M105a in a predetermined region. This forms the opening H101 above the drain electrode 106B as illustrated in FIG. 4F. The drive substrate according to the comparative example is manufactured as described above.

In the comparative example using the drain electrode as an anode as described above, five photomasks are used to manufacture the drive substrate in the photolithography process. The photolithography process tends to result in high cost because of photomasks, photoresist and other members that are necessary for the process. Further, the process includes a number of steps such as photoresist coating, exposure and peeling-off, thus resulting in a larger number of film formation steps. It is, therefore, preferred that the number of patterning steps based on photolithography should be as small as possible.

In the present embodiment, therefore, the semiconductor layer 12 of the transistor section 10B is divided in terms of functionality so that part thereof serves as the pixel electrode section 12C (the semiconductor layer 12 is used as an anode), thus ensuring a reduced number of steps in the photolithography process. Further, only four photomasks are used during manufacture of the drive substrate, thus contributing to less consumption of photoresist and other members.

As described above, in the present embodiment, the gate insulating film 13 and gate electrode 14 are provided in a selective region (channel region 12A) on the semiconductor layer 12 composed of an oxide semiconductor. The source/drain electrode layer 16 is electrically connected to the region (source/drain connection region 12B) adjacent to the channel region 12A. In the semiconductor layer 12, a region (pixel electrode section 12C) different from the channel region 12A or source/drain connection region 12B is used as an anode. This contributes to less consumption of photomasks, photoresist and other members and a smaller number of steps in the manufacturing process, thus allowing for manufacture of the display device by a low-cost and simple process.

Further, the source/drain connection region 12B and pixel electrode section 12C of the semiconductor layer 12 are subjected to plasma treatment. This contributes to reduced electrical resistivity, thus providing enhanced functionality of the oxide semiconductor material serving as an electrode or electrical connection region.

Still further, the photoresist used for the patterning of the source/drain electrode layer 16 is left unremoved as the protective film 17, thus ensuring insulation between the source/drain electrode layer 16 and functional layer 18. Still further, the unremoved protective film 17 is reflowed, fully covering the source/drain electrode layer 16 for enhanced insulation.

### [Configuration of the Display Device and Pixel Circuit Configuration]

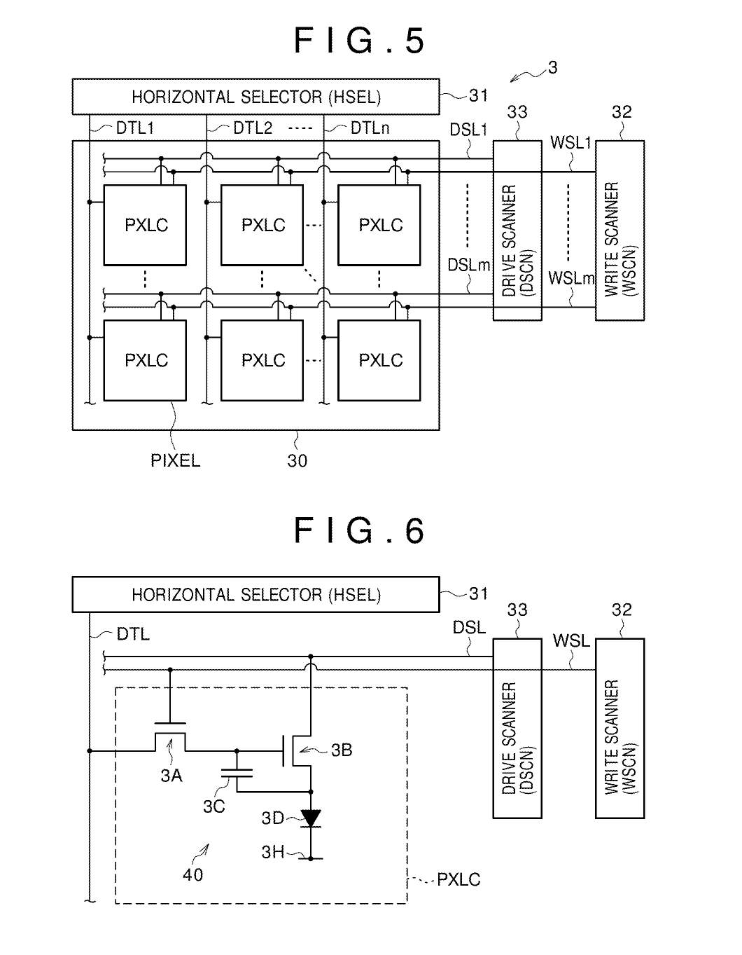

A description will be given next of the overall configuration of the display device 1 according to the above embodiment and the pixel circuit configuration thereof. FIG. 5 illustrates the overall configuration including peripheral circuitry of the display device used as an organic EL display. As described above, a display region 30 is formed on the substrate 11. The display region 30 has, for example, a plurality of pixels PXLC arranged in a matrix form. Each of the pixels PXLC includes an organic EL element. A horizontal selector (HSEL) 31, write scanner (WSCN) 32 and drive scanner (DSCN) 33 are provided around the display region 30. The horizontal selector 31 serves as a signal drive circuit. The write scanner 32 serves as a scan line drive circuit. The drive scanner 33 serves as a power line drive circuit.

In the display region 30, a plurality (integer n) of signal lines DTL1 to DTLn are arranged in the column direction, with a plurality (integer m) of scan lines WSL1 to WSLm and power lines DSL1 to DSLm arranged in the row direction. Further, the pixel PXLC (one of red, green and blue pixels) is provided at each of the intersections between one of the signal lines DTL and one of the scan lines WSL. Each of the signal lines DTL is connected to the horizontal selector 31 so that a video signal is supplied from the horizontal selector 31 to each of the signal lines DTL. Each of the scan lines WSL is connected to the write scanner 32 so that a scan signal (selection pulse) is supplied from the write scanner 32 to each of the scan lines WSL. Each of the power lines DSL is connected to the drive scanner 33 so that a power signal (control pulse) is supplied from the drive scanner 33 to each of the power lines DSL.

FIG. 6 illustrates a specific circuit configuration example of the pixel PXLC. Each of the pixels PXLC has a pixel circuit 40a including an organic EL element 3D. The pixel circuit 40a is an active drive circuit having a sampling transistor 3A, drive transistor 3B and holding capacitor 3C and the organic EL element 3D. Of these components, the transistor 3A (or transistor 3B) corresponds to the transistor section 10B in the above embodiment.

The sampling transistor 3A has its gate connected to the associated scan line WSL, one of its source and drain to the associated signal line DTL, and the other of its source and drain to the gate of the drive transistor 3B. The drive transistor 3B has its drain connected to the associated power line DSL and its source to the anode of the organic EL element 3D. On the other hand, the cathode of the organic EL element 3D is connected to a grounding interconnect 3H. It should be noted that the grounding interconnect 3H is shared by all the pixels PXLC. The holding capacitor 3C is arranged between the source and gate of the drive transistor 3B.

The sampling transistor 3A goes into conduction in response to a scan signal (selection pulse) supplied from the scan line WSL, thus sampling the video signal potential supplied from the signal line DTL and allowing the potential to be held by the holding capacitor 3C. The drive transistor 3B is supplied with a current from the power line DSL at a predetermined first potential (not shown), thus supplying a drive current commensurate with the video signal potential held by the holding capacitor 3C to the organic EL element 3D. When supplied with the drive current from the drive transistor 3B, the organic EL element 3D emits light at the brightness commensurate with the signal potential held by the holding capacitor 3C.

In such a circuit configuration, the sampling transistor 3A goes into conduction in response to a scan signal (selection pulse) supplied from the scan line WSL, thus sampling the video signal potential supplied from the signal line DTL and allowing the potential to be held by the holding capacitor 3C. Further, a current is supplied from the power line DSL at the predetermined first potential (not shown) to the drive transistor 3B, thus supplying a drive current commensurate with the signal potential held by the holding capacitor 3C to the organic EL element 3D (one of the red, green and blue organic EL elements). When supplied with the drive current from the drive transistor 3B, the organic EL element 3D emits light at the brightness commensurate with the video signal potential held by the holding capacitor 3C, thus allowing for an image to be displayed on the display device based on the video signal.

### APPLICATION EXAMPLES

A description will be given below of application examples (module and application examples 1 to 5) of the above display device to electronic equipment. Among examples of electronic equipment are television set, digital camera, laptop personal computer, personal digital assistance such as mobile phone and video camcorder. In other words, the above display device is applicable to electronic equipment across all disciplines adapted to display a video signal fed thereto or generated therein as an image or picture.

### (Module)

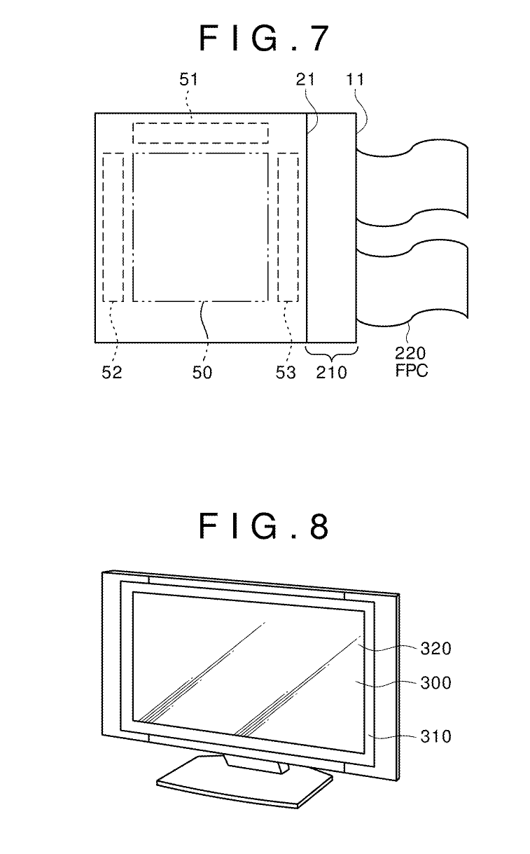

The above display device is built into a variety of electronic equipment including application examples 1 to 5 as a module as shown, for example, in FIG. 7. This module is manufactured, for example, as follows. That is, a region 210 exposed from a sealing substrate 60 is provided on one side of the substrate 11. Then, the interconnects of the horizontal selector 51, write scanner 52 and drive scanner 53 are extended to the region 210, thus forming external connection terminals (not shown). An FPC (flexible printed circuit) 220 adapted to exchange signals may be provided on the external connection terminals.

### Application Example 1

FIG. 8 illustrates the appearance of a television set. This television set has, for example, a video display screen section 300 including a front panel 310 and filter glass 320. The video display screen section 300 corresponds to the above display device 1.

### Application Example 2

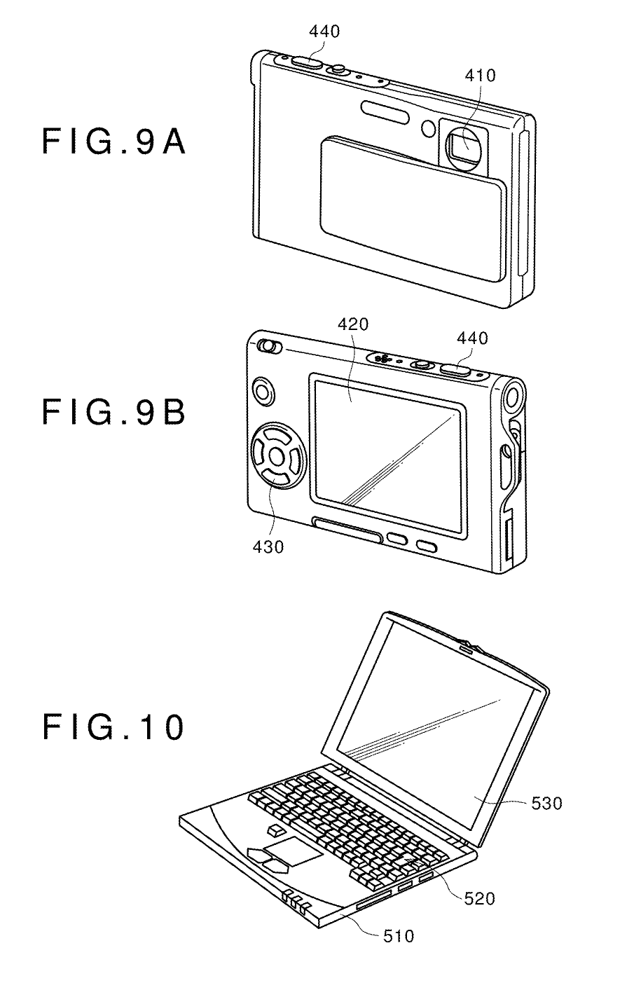

FIGS. 9A and 9B illustrate the appearance of a digital camera. This digital camera has, for example, a flash-emitting section 410, display section 420, menu switch 430 and shutter button 440. The display section 420 corresponds to the above display device 1.

### Application Example 3

FIG. 10 illustrates the appearance of a laptop personal computer. This laptop personal computer has, for example, a main body 510, keyboard 520 adapted to be manipulated for entry of text or other information and a display section 530 adapted to display an image. The display section 530 corresponds to the above display device 1.

### Application Example 4

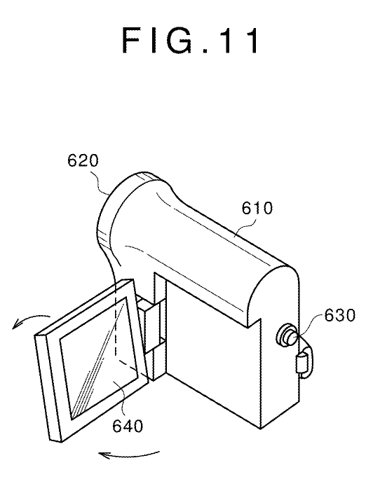

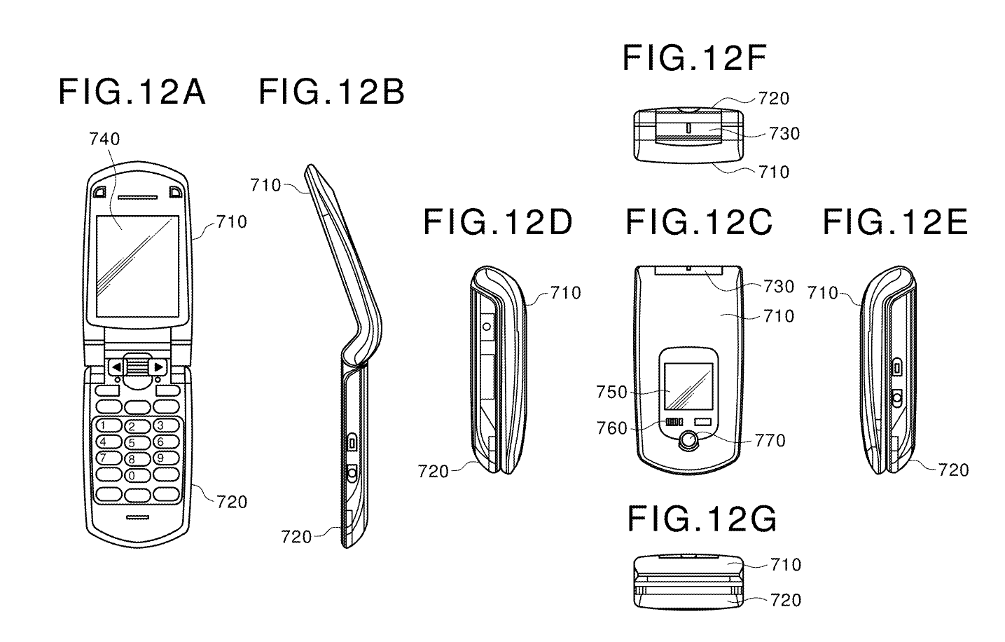

FIG. 11 illustrates the appearance of a video camcorder. This video camcorder has, for example, a main body section 610, lens 620 provided on the front-facing side surface to capture the image of the subject, imaging start/stop switch 630 and display section 640. The display section 640 corresponds to the above display device 1.

### Application Example 5

FIGS. 12A to 12G illustrate the appearance of a mobile phone. This mobile phone is made up, for example, of an upper enclosure 710 and lower enclosure 720 that are connected together with a connecting section (hinge section) 730 and has a display 740, subdisplay 750, picture light 760 and camera 770. Each of the display 740 and subdisplay 750 corresponds to the above display device 1.

Although the present disclosure has been described above with reference to the preferred embodiment, the present disclosure is not limited thereto and may be modified in various ways. For example, an example has been described in the preferred embodiment in which the lower (pixel electrode) of the two electrodes sandwiching the organic EL layer serves as an anode, and the upper (common electrode) thereof as a cathode. In contrast to the above, however, the lower electrode may serve as a cathode, and the upper electrode as an anode.

The present disclosure contains subject matter related to that disclosed in Japanese Priority Patent Application JP 2011-066282 filed in the Japan Patent Office on Mar. 24, 2011, the entire content of which is hereby incorporated by reference.

What is claimed is:

1. A display device comprising:
a semiconductor layer provided on a substrate and made of an oxide semiconductor;
a gate electrode provided above a selective first region of the semiconductor layer with a gate insulating film sandwiched therebetween;
a source/drain electrode layer adapted to serve as a source or drain and electrically connected to a second region of the semiconductor layer adjacent to the first region thereof; and
an organic electric field light-emitting element provided above a third region of the semiconductor layer different from the first and second region thereof, the organic electric field light-emitting element having a region for the third region that is driven as a pixel electrode.

2. The display device according to claim 1, wherein
the second and third regions are lower in electrical resistivity than the first region.

3. The display device according to claim 2 comprising:
an interlayer insulating film adapted to cover the gate insulating film and gate electrode, the interlayer insulating film having a first opening for the second region and a second opening for the third region, wherein
the source/drain electrode layer is provided in the region for the first opening of the interlayer insulating film, and the organic electric field light-emitting element is provided in the region for the second opening of the interlayer insulating film.

4. The display device according to claim 3, wherein
the interlayer insulating film is made of a photosensitive resin.

5. The display device according to claim 3, wherein
the source/drain electrode layer is provided on the interlayer insulating film in such a manner as to fill the first opening, the display device further comprising:
a protective film adapted to cover the source/drain electrode layer on the interlayer insulating film.

6. The display device according to claim 5, wherein
the protective film is made of a photosensitive resin.

7. A manufacturing method of a display device comprising:
forming a semiconductor layer made of an oxide semiconductor on a substrate;
forming a gate electrode above a selective first region of the semiconductor layer with a gate insulating film sandwiched therebetween;
forming a source/drain electrode layer adapted to serve as a source or drain in such a manner to electrically connect the source/drain electrode layer to a second region of the semiconductor layer adjacent to the first region thereof; and
forming an organic electric field light-emitting element above a third region of the semiconductor layer different from the first and second region thereof, the organic electric field light-emitting element having a region for the third region that is driven as a pixel electrode.

8. The manufacturing method of a display device according to claim 7, wherein
a plasma treatment is performed following the formation of the gate electrode so as to reduce the electrical resistivity of the second and third regions to a level lower than that of the first region.

9. The manufacturing method of a display device according to claim 8 comprising:
following the plasma treatment and prior to the formation of the source/drain electrode layer, forming an interlayer insulating film adapted to cover the gate insulating film and gate electrode, the interlayer insulating film having a first opening for the second region and a second opening for the third region, wherein
the source/drain electrode layer is provided in the region for the first opening of the interlayer insulating film, and the organic electric field light-emitting element is provided in the region for the second opening of the interlayer insulating film.

10. The manufacturing method of a display device according to claim 9, wherein
a photosensitive resin is used as the interlayer insulating film.

11. The manufacturing method of a display device according to claim 9, wherein
during the formation of the source/drain electrode layer, the source/drain electrode layer is formed on the interlayer insulating film in such a manner as to fill the first opening first, and then the source/drain electrode layer is patterned by photolithography.

12. The manufacturing method of a display device according to claim 11, wherein
a photosensitive resin used for the patterning of the source/drain electrode layer is heated for reflow so as to form a protective film adapted to cover the source/drain electrode layer on the interlayer insulating film.

13. Electronic equipment comprising:
a display device including
a semiconductor layer provided on a substrate and made of an oxide semiconductor;
a gate electrode provided above a selective first region of the semiconductor layer with a gate insulating film sandwiched therebetween;
a source/drain electrode layer adapted to serve as a source or drain and electrically connected to a second region of the semiconductor layer adjacent to the first region thereof; and
an organic electric field light-emitting element provided above a third region of the semiconductor layer different from the first and second region thereof, the organic electric field light-emitting element having a region for the third region that is driven as a pixel electrode.
